(19) United States
(12) Patent Application Publication
(10) Pub. No.: US 2007/0128762 A1
(43) Pub. Date: Jun. 7, 2007

(54) Growing crystaline structures on demand

(75) Inventors: Joanna Aizenberg, New Providence, NJ (US); Yong-Jin Han, Pleasanton, CA (US)

Correspondence Address: HITT GAINES, PC;LUCENT TECHNOLOGIES INC., PO BOX 832570, RICHARDSON, TX, 75083, US

(73) Assignee: Lucent Technologies Inc., Murray Hill, NJ (US)

(21) Appl. No.: 11/292,982

(22) Filed: Dec. 2, 2005

(51) Int. Cl. H01L 51/40; C30B 11/00; H01L 21/20

(52) U.S. Cl. 438/99; 438/478; 117/200

(57) ABSTRACT

An apparatus comprising a substrate having a surface with at least one crystallization nucleation site located thereon. The apparatus further comprises a second substrate having a second surface. The second surface is configured to maintain a crystallization starting material in an amorphous state or an initial crystalline state. The crystallization nucleation site is configured to impose a property on the crystallization starting material

### TECHNICAL FIELD OF THE INVENTION

The present invention is directed, in general, to an apparatus and method for forming crystalline structures on a surface.

### BACKGROUND OF THE INVENTION

There is a long-standing need for a process to mass-produce crystals having a pre-selected property, e.g., orientation, surface coverage, location, shape, or composition. Current processes form crystals with random orientations and not with well-controlled location. The crystal with the desired orientation is handpicked and then transported to the device that will comprise the crystal, or separately grown, polished in a desired orientation and then placed in the needed location. Manually selecting crystals is impractical for fabricating large number of devices, such as when assembling a plurality of transistors on a single substrate surface. Moreover, the crystals can be damaged during their handling and transport thereby reducing device yields and increasing the cost and time for device fabrication.

### SUMMARY OF THE INVENTION

To address the above-discussed deficiencies, one embodiment is an apparatus. The apparatus comprises a substrate having a surface with at least one crystallization nucleation site located thereon. The apparatus also includes a second substrate having a second surface. The second surface is configured to maintain a crystallization starting material in an amorphous state or an initial crystalline state. The crystallization nucleation site is configured to impose a property on the crystallization starting material.

Another embodiment is a method. The method includes providing a substrate with a surface, a crystallization nucleation site located on the surface. The method also includes contacting the crystallization starting material with a second surface of a second substrate. The second surface maintains a crystallization starting material in an amorphous state or an initial crystalline state until the crystallization starting material contacts the crystallization nucleation site. The method further includes growing a crystalline structure from the crystallization starting material on the crystallization nucleation site by changing a property of the crystallization starting material imposed by the crystallization starting material.

### BRIEF DESCRIPTION OF THE DRAWINGS

The embodiments are best understood from the following detailed description, when read with the accompanying figures. Various features may not be drawn to scale and may be arbitrarily increased or reduced in size for clarity of discussion. Reference is now made to the following descriptions taken in conjunction with the accompanying drawings, in which:

FIG. 1 present a cross-sectional view of an exemplary apparatus;

FIG. 2 present a cross-sectional view of a second exemplary apparatus;

FIG. 3 present a cross-sectional view of a third exemplary apparatus;

FIG. 4 present a cross-sectional view of a fourth exemplary apparatus;

FIG. 5 present a cross-sectional view of a fifth exemplary apparatus; and

FIG. 6 presents a flow diagram of an exemplary method.

### DETAILED DESCRIPTION

At least some of the above-described deficiencies are overcome by embodiments where crystalline structures are formed on demand using a crystallization nucleation site. The crystallization nucleation site causes a crystallization starting material to crystallize from an amorphous material, or, to change from one crystal polymorph to another crystal polymorph. A polymorph refers to a crystal that is identical to another crystal in chemical composition but differs from its lattice structure, or is identical to another crystal in lattice structure but differs from its macroscopic shape. Moreover, by altering the chemical composition of the crystallization nucleation site, different predefined properties can be imposed on the crystalline structures. Additionally, if desired, the starting material can be stored for long periods by contacting it with a surface configured to maintain the crystallization starting material in its pre-crystalline state.

The term crystalline structure, as used herein, refers to a solid material whose constituent atoms, ions, or molecules form a pattern possessing long-range internal order in three dimensions. The crystalline structure can be a single crystal or crystallites (e.g., small crystals having one or more microscopic dimension).

The term amorphous material as used herein refers to a liquid or solid substance whose constituent atoms, ions, or molecules do not have long-range internal order in three dimensions. One of ordinary skilled in the art would be familiar with the procedures used to determine whether or not a material is amorphous. For example, an x-ray powder pattern of an amorphous material would have no discernable peaks. In some cases the amorphous material can include a solution of the substance. In other cases the amorphous material can be a melt of the substance, which is substantially devoid (e.g., less than 1 wt %) of solvent.

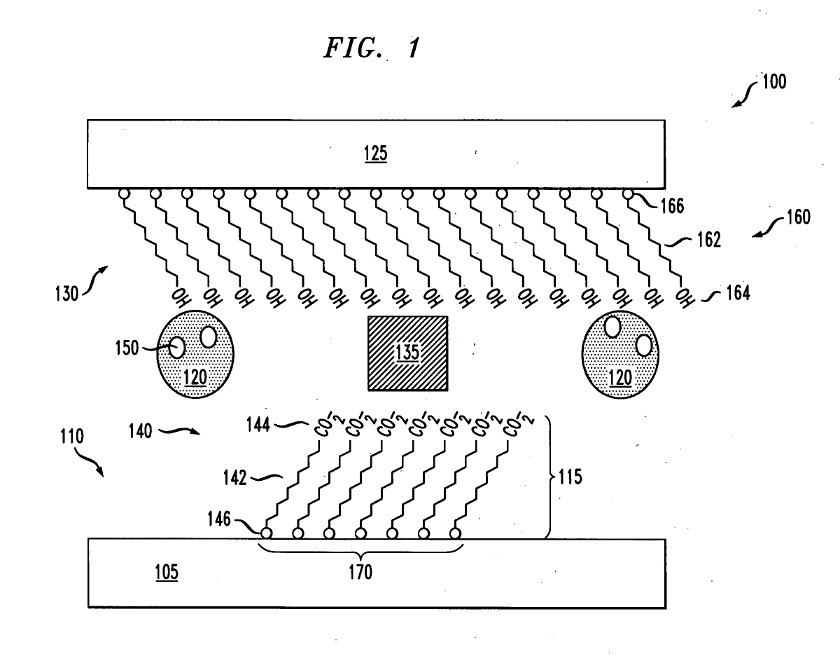

One embodiment is an apparatus. FIG. 1 presents a cross-sectional view of an exemplary apparatus 100. The apparatus 100 comprises a substrate 105 having a surface 110 with at least one crystallization nucleation site 115 thereon. The apparatus 100 also includes a crystallization starting material 120. The crystallization nucleation site 125 is configured to impose a property on the crystallization starting material 120.

It is advantageous for the apparatus 100 to further include a second substrate 125 having a second surface 130. The second surface 130 can be configured to maintain the crystallization starting material 120 in an amorphous state or a particular initial crystalline state. This is a critical advantage in cases where one wishes to hold the starting material 120 in reserve for a period before using the apparatus 100.

Another critical feature of the apparatus 100 is the ability of the crystallization nucleation site 115 to impose a property on the starting material 120. The imposed property can be displayed by a crystalline structure 135 formed from the crystallization starting material 120. For example, FIG. 1 shows the apparatus 100 where a portion of the crystallization starting material 120, here an amorphous material, has changed its property by forming a crystalline structure 135.

The imposed property could be any number of structural characteristics that distinguishes the starting material 120 from the crystalline structure 135, and which is predetermined by the nucleation site 115. For example, the imposed property can be the crystallographic orientation of the crystalline structure 135. As another example, the imposed property can be a predefined crystalline morphology of the crystalline structure 135 formed from the crystallization starting material 120. The term crystalline morphology as used herein refers to the macroscopic shape formed by the combination of faces of the crystalline structure. Examples of crystalline morphologies of the crystalline structure 135 are polyhedral-shaped structures such as a pyramid, prism, cube, octahedron, tetrahedron, dodecahedron, or rhombohedron. As noted above, the crystalline structure 135 can be formed from an amorphous or crystalline starting material 120. In the former case, the imposed property can be the transition from amorphous to crystalline via the formation of a predefined crystalline morphology. In the latter case, the imposed property can be a transition from one crystalline morphology to a different predefined crystalline morphology.

The chemical composition and shape of the crystallization nucleation site 115 is configured to impose the desired property on the starting material 120. Consider, as an example, a starting material 120 that is an amorphous material comprising inorganic compound such as calcium carbonate. The desired property imposed is a transition from amorphous calcium carbonate to calcite crystals. To impose this property, the crystallization nucleation site 115 can comprise a self-assembling monolayer 140 such as illustrated in FIG. 1. The self-assembling monolayer 140 shown in FIG. 1 comprises acyclic hydrocarbon chains 142, in this case, an alkyl chain. Each chain 142 is terminated on one end 144 with a functional group. The other end 146 can be anchored to the substrate's surface 105. For example, an anchoring end 146 of an alkane chain 142 can be terminated with a thiol group to facilitate covalent bonding to a substrate surface 110 covered with gold.

The chemical composition of crystallization nucleation site 115 can be configured to impose a property of a predefined crystal orientation on the starting material 120. As further illustrated in FIG. 1, the self-assembling monolayer 140 can comprise a plurality of molecules having the formula: —S—(CH₂)ₙ—COO⁻, where the functionalized end 144 of an alkane chain 142 corresponds to the carboxylic acid functional group, the anchoring end 146 corresponds to the thiol group, and n is the number of —CH₂— units in the chain 142. By configuring the alkane chain 142 to have ten or other even numbers of —CH₂— units (e.g., n=2, 4, 6, etc . . . ) a rhombohedral cube crystalline structure 135 having a (11l) nucleating plane (e.g., where l is from about 2 to 5) can be imposed. Configuring the alkane chain 142 to have fifteen or other odd numbers of —CH₂— units (e.g., n=1, 3, 5, etc . . . ) can impose a rhombohedral cube having a (01) nucleating plane (e.g., where l is about 3).

Of course, the self-assembling monolayer 140 can comprise molecules having an end 144 with alternative functional groups (e.g., phosphonic acid, sulfonic acid, or hydroxyl) or chain lengths (e.g., n ranging from 1 to 20), to impose other properties (e.g., different orientations) on the starting material 120.

The starting material 120 can also comprise one or more additive 150. The additive 150 can comprise an inorganic or organic molecule or polymer. The additive 150 can affect one or more of the properties imposed by the crystallization nucleation site 115. For instance, exposing the site 115 to an additive-containing starting material 120 can cause the crystalline structure 135 to form different crystal morphologies. Thus, by adjusting the concentration or type of additive 150, the additive 150 can thereby affect the property of the crystalline structure 135. Continuing with the same example as presented above, the amorphous calcium carbonate starting material 120 can include an additive 150 comprising magnesium (e.g., about 50 wt %). A self-assembling monolayer 140 comprising carboxylic acid-functionalized alkane chains exposed to magnesium-containing amorphous calcium carbonate starting material 120 imposes the formation of seed-shaped calcite crystalline structures 135. This is in contrast to a magnesium-free amorphous calcium carbonate starting material 120, which under similar conditions, forms rhombohedral cube-shaped calcite crystalline structures 135.

As noted above, it can be advantageous to hold the starting material 120 in reserve on a second substrate 125 configured to maintain the crystallization starting material 120 in an amorphous state or a particular crystalline polymorph. In the present example, as illustrated in FIG. 1, the surface 130 of the second substrate 125 can comprise a second self-assembling monolayer 160 configured to perform this function. The second self-assembling monolayer 160 can be composed of the same types of molecules as in the first self-assembling monolayer 140. However, the two self-assembling monolayers 140, 160 do not have identical chemical compositions. For instance, as shown in FIG. 1, each alkyl chain 162 is terminated on one end 164 with a hydroxyl functional group and other end 166 is anchored to the second substrate's gold-covered surface 130 via a thiol group. The property of the starting material 120 is imposed when the second surface 130 holding the starting material 120 is brought into contact with the first surface 110 having the crystallization nucleation sites 115.

A patterned distribution of crystalline structures 135 can be formed on the surface 110, for example, by forming the crystallization nucleation site 115 at predefined locations 170 on the surface 110.

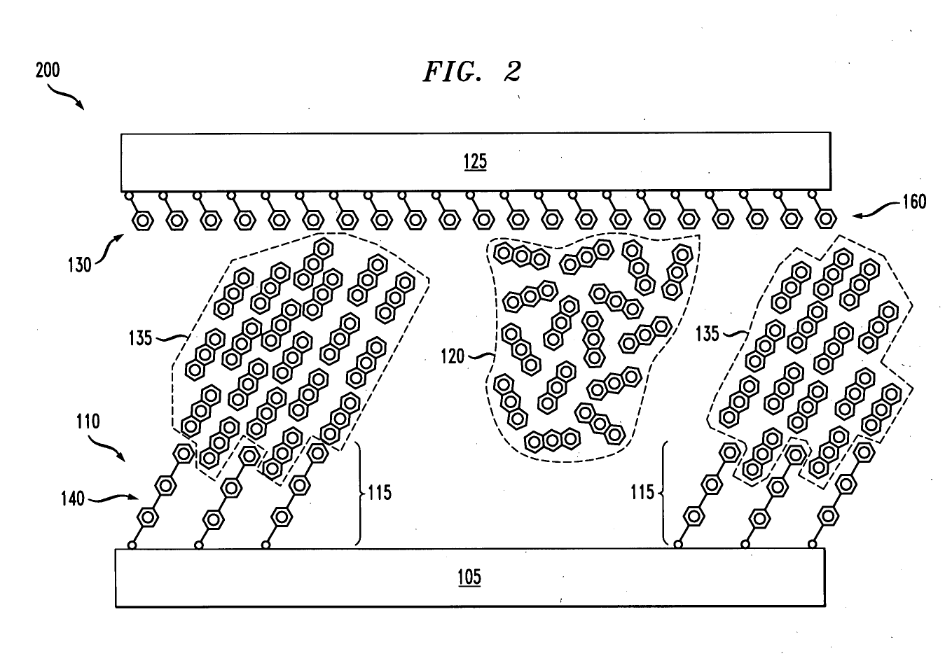

FIG. 2 presents a cross-sectional view of a second exemplary apparatus 200. Similar reference numbers are used to illustrate elements of the apparatus 200 that are analogous to the apparatus shown in FIG. 1. FIG. 2 demonstrates how the chemical composition of the crystallization nucleation site 115 can be configured to impose the desired property on an organic starting material 120. In this example, the starting material 120 is an amorphous material comprising organic semiconductor molecules. The starting material 120 can comprise organic semiconducting molecules, such as anthracene as shown in the figure. In other cases, however, the starting material can comprise other organic semiconducting molecules such as tetracene or pentacene.

Again, the property imposed can be a transition from an amorphous to crystalline structure. To impose this property, the crystallization nucleation site 115 can comprise a self-assembling monolayer 140 of oligophenylenes, such as thiophenyl; biphenylthiol, or terphenylthiol. As illustrated in FIG. 2, the thiol group of a terphenylthiol can serve as an anchor end 166 for attachment to the first substrate's gold surface 110. In other cases, the self-assembling monolayer 140 can comprise other materials well known to those of ordinary skill in the art.

As further illustrated in FIG. 2, one can hold the starting material 120 in reserve until the desired time and place to impose the property change. As shown in the figure, a starting material 120 of anthracene is held in its amorphous state by a second self-assembling monolayer 160 attached to the second surface 130 of a second substrate 125. As illustrated in the figure, the second self-assembling monolayer 160 comprises an alkyl thiol. For example, the self-assembling monolayer 160 can comprise an alkane thiol having the formula: —S—(CH₂)ₘ—CH₃, where m ranges from 1 to 20. As another example, the self-assembling monolayer 160 can comprise a functionalized alkane thiol having the formula: —S—(CH₂)₁—R, where l ranges from 1 to 20, and R is an amine (NH₂), hydroxyl (OH), carboxylic acid (COOH) or other functional group. Of course, in other embodiments, the second self-assembling monolayer 160 can comprise similar but non-identical molecules as the first self-assembling monolayer 140. For example, the second self-assembling monolayer 160 can comprise molecules of mercaptopurine, advantageously allowing a solution of the starting material 120 to be spin-coated while in an amorphous phase.

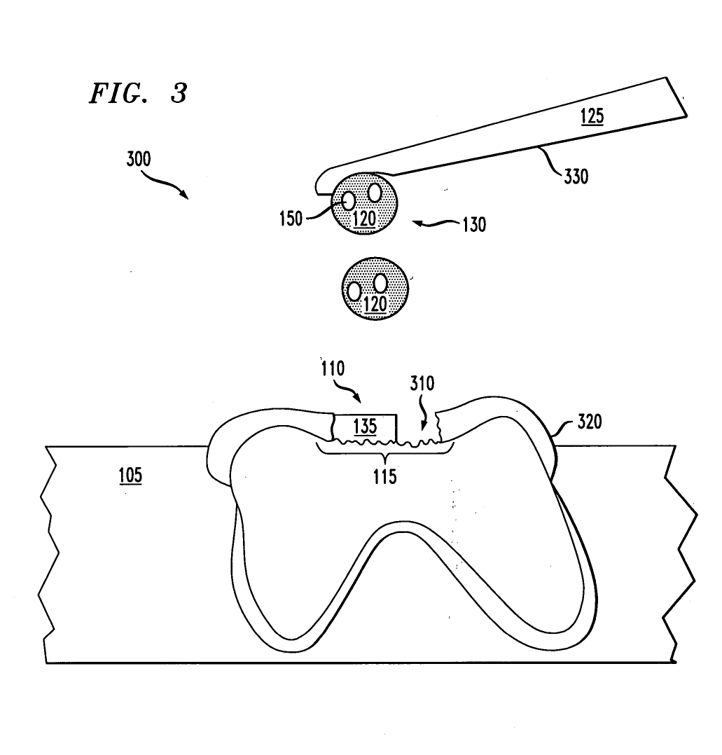

FIG. 3 presents a cross-sectional view of a third exemplary apparatus. Again, similar reference numbers are used to illustrate elements of the apparatus 300 that are analogous to the apparatus shown in FIG. 1. In this embodiment, the crystallization starting material 120 is a tissue replacement material and the crystallization nucleation site 115 is located at the surface 110 in an opening 310 of the substrate 105. As illustrated in FIG. 3, the substrate 105 can comprise a tissue, such as a tooth 320 (or bone), having the opening 310. The opening 310 can be a damaged area formed due to a fracture or cavity in the tooth 320, for instance. Rough surfaces 110 comprising e.g., defect sites with multiple pits and trenches, in the opening 300 more actively promote various chemical and physical processes due to their inherently high surface energy. This brings about high affinity to small crystallites and can serve as the crystallization nucleation site 115. Due to their high surface energy, these sites could selectively interact with other species in solution. For example, they can be pretreated with specialized bio-organic molecules that will selectively adsorb on the rough surfaces 110, to further facilitate the nucleation process.

The starting material 120 can be amorphous or crystalline calcium phosphate. For example, the starting material 120 can be a sol-gel solution consisting of calcium and phosphate ions that is easy to form and stable. Contacting the starting material 120 to the crystallization nucleation site 115 imposes a change in property corresponding to a transition from the amorphous sol solution to a crystalline structure 135 comprising hydroxyapatite. Moreover, the crystallization nucleation site 115 is only located in the opening 310 having the rough surface 110. Consequently, the crystalline structure 135 forms only in the opening 310 and not on other areas of the substrate 105.

Of course, similar to the above-described embodiments of the apparatus, the starting material 120 can be maintained in its initial amorphous or crystal configuration by contacting it to a second substrate 125 have a second surface 130. For example, the second substrate 125 can be an applicator such as a filling tool 330 that has a second surface 130 comprising phosphate-terminated alkyl thiols, adenosine triphosphate (ATP), phosphopeptides, or biphosphates.

The starting material 120 could also include a variety of additives 150. For example, fluorescent molecules, such as green fluorescent protein from the jelly fish Aequorea victoria Can be included as an additive 150 to facilitate visualization of the starting material 120 or crystalline structure 135. Proteins (e.g., avidin or biotin) can be included as additives 150 to improve biocompatibility and binding to the substrate 105 surface 110. Drugs (e.g., antibiotics or ibuprofen) can be included as an additive 150 to prevent tissue inflammation.

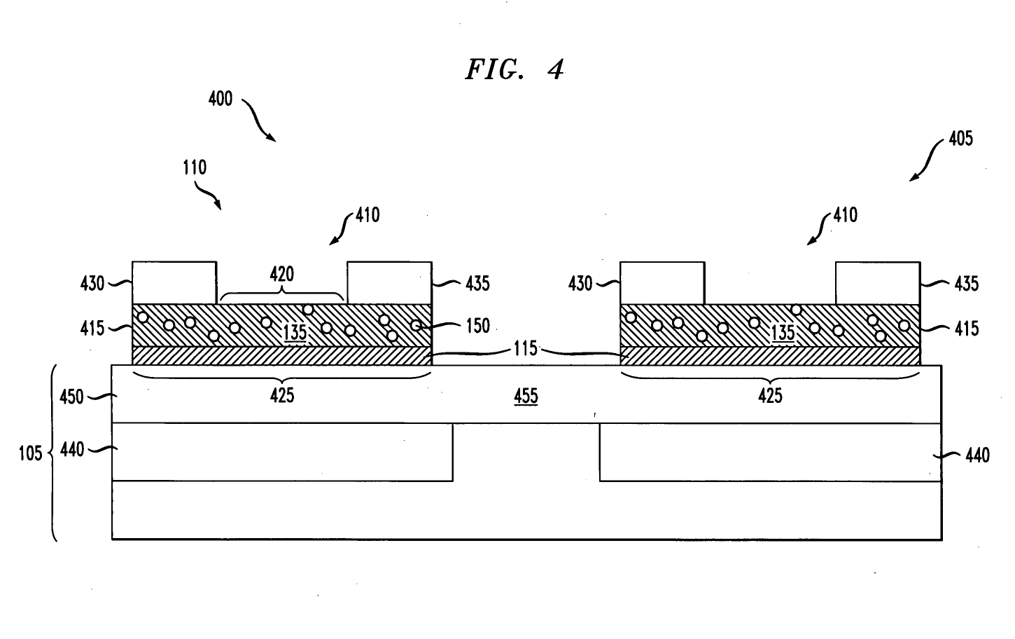

FIG. 4 presents a cross-sectional view of a fourth exemplary apparatus 400, with similar reference numbers used to illustrate elements of the apparatus 400 that are analogous to the apparatus shown in FIG. 1. As illustrated in FIG. 4, the apparatus 400 can include one or more electrical circuits 405 located on the surface 110 of the substrate 105. The electrical circuits 405 can comprise one or more field-effect transistors 410, such as organic field-effect transistors (OFETs). The semiconductor layer 415 of the transistors 410 comprises the crystalline structures 135. Thus, an active channel 420 of field-effect transistor 410 is composed of the crystalline structure 135.

The crystalline structure 135 can be made of any of the crystals or crystallites formed from the crystallization starting material 120 as discussed above, e.g., in the context of FIGS. 1-2. For example, the crystalline structure 135 can include organic semiconductor molecules such as anthracene, tetracene or pentacene. Conventional micro-patterning methods can be used to deposit crystallization nucleation sites 115 on separated areas 425 of the substrate surface 110. This can provide a plurality of physically separated crystallization nucleation sites 115. The crystalline structure 135 is thereby formed only at the selected areas 425, thereby allowing the formation of a plurality of semiconductor layers 415 in a single step. For example, in some embodiments of the apparatus 400, a one- or two-dimensional array of crystalline structures 135 can be grown on the substrate surface 110. This, in turn, can facilitate the formation of a plurality of transistors 410 on the surface 110.

The crystalline structure 135 can further include additives 150 that alter the property imposed by the crystallization nucleation site 115 as discussed above. For instance, it can be advantageous to include additives in the starting material so that when the starting material is transformed into the crystalline structure the additives will be homogenously distributed throughout the crystalline structure 135.

The transistors 410 can include other device components to provide an operative circuit 405. The transistors 410 shown in FIG. 4 includes source and drain electrodes 430, 435, gate 440 and gate dielectric layer 450. One of ordinary skill in the art would be familiar with suitable conventional materials to form these components. For example, the planar substrate 105 can be made of silicon, or more flexible organic materials such as plastics, for example polyethylene terephthalate (PET) . The gate 440 can comprise doped silicon. In other cases, materials more conducive to forming a flexible device, such as indium tin oxide (ITO), can be used. Similarly, the gate dielectric layer 450 can comprise silicon dioxide, or more flexible materials, such as polymer dielectrics like polybutyl methacrylate (PBMA). The source and drain electrodes 430, 435 can comprise gold or other electrically conductive metals or non-metals, such as electrically conductive polymers.

In some cases, the gate dielectric layer 450 can also comprise a second crystalline structure 455. The second crystalline structure 455 can be formed in a similar fashion as used formed the crystalline structure 135 of the semiconductor layer 415. Of course, the crystalline structure 455 of the gate dielectric layer 450 would have a different chemical composition than the crystalline structure 135 of the semiconductor layer 415.

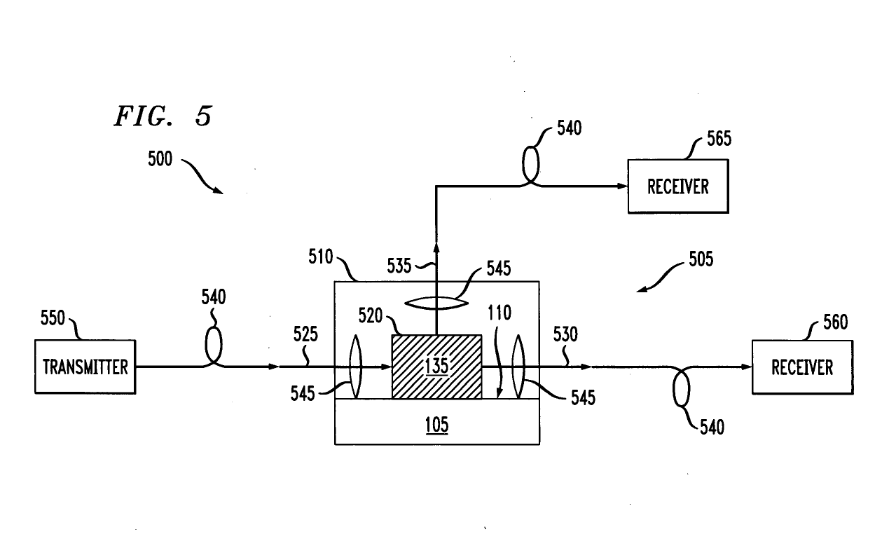

FIG. 5 present a cross-sectional view of a fifth exemplary apparatus 500 with similar reference numbers used to illustrate elements of the apparatus 500 that are analogous to the apparatus shown in FIG. 1. An optical circuit 505 is on the surface 110 of the substrate 105. The optical circuit 505 depicted in FIG. 5 comprises a polarization beam splitter 510. The crystallization starting material 135 comprises a birefringent material 520 of the polarization beam splitter 510. The birefringent material 520 is configured to split an incident beam of light 525 into two output components 530, 535. In some preferred embodiments, the birefringent material 520 comprises calcite crystals formed similar to that described above in the context of FIG. 1.

One of ordinary skill in the art would understand that the optical circuit 505 could include other conventional components, such as optical fibers 540 and lenses that couple light 525, 530, 535 to and away from the polarization beam splitter 510, a transmitter 550, such as a laser, and a receivers 560, 565 to make the apparatus 500 operative. One skilled in the art would further recognize how components comprising the crystalline structure 135 could be advantageously incorporated in optical fiber communication, liquid crystal display, or other optical systems. For example, it would be readily apparent to one skilled in the art how to use the crystalline structure 135 in an optical polarization combiner.

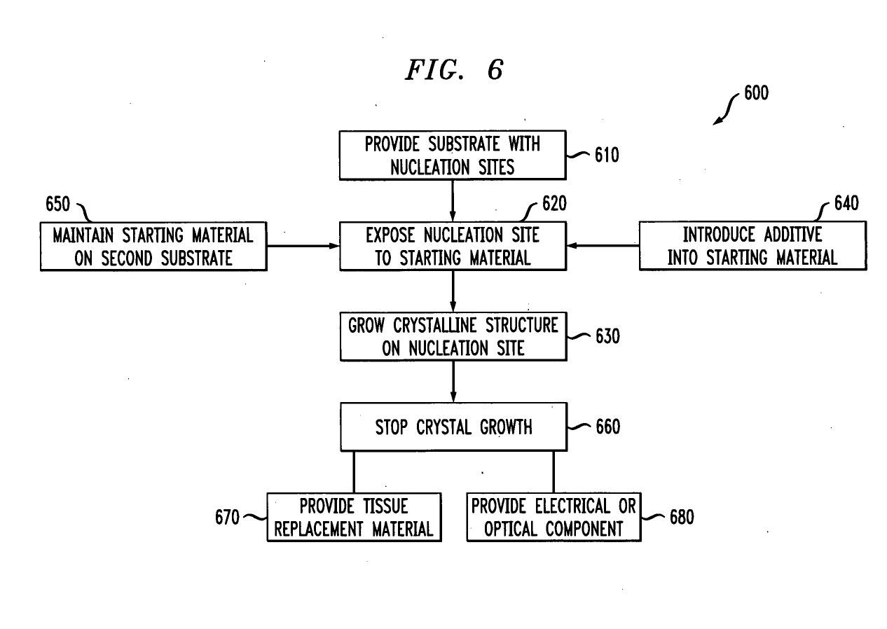

Another embodiment is a method. FIG. 6 presents a flow diagram of an exemplary method 600. A substrate with a surface having one or more crystallization nucleation site located thereon is provided in step 610. The substrate can include any conventional material, including the materials discussed above in the context of FIGS. 1-5. The substrate can also include device component layers such as a bottom gate 440 and dielectric layer 450 in the case of OFETs 410 such as illustrated in FIG. 4. The crystallization nucleation site can include any of the materials discussed above in the context of FIGS. 1-5. For example, each crystallization nucleation site can comprise a self-assembling monolayer, crystal seed or other organic or bioorganic molecules that induce crystal nucleation.

In step 620, the substrate surface having the crystallization nucleation site is exposed to a crystallization starting material. Step 630 comprises growing a crystalline structure on the crystallization nucleation site by changing a property of the starting material.

The crystallization starting material can comprise any of the materials discussed above in the context of FIGS. 1-5. For instance, the crystallization starting material can comprise a solid or liquid amorphous material that is transformed into the crystalline structure upon contacting the crystallization nucleation site. Alternatively, the crystallization starting material can comprise a second crystalline structure that is transformed into the desired crystalline structure upon contacting the crystallization nucleation site. Changing the property of the starting material can comprise changing the starting material from an amorphous state to the crystalline structure or from an initial crystalline structure to a different crystalline structure.

The crystalline structure grown in step 630 can be crystallites or a crystal. For example, as discussed above in the context of FIGS. 1-5, the crystalline structure can comprise inorganic or organic crystals, organic semiconductor, dielectric, birefringent or tissue replacement materials.

As further illustrated in FIG. 6, in some cases it is desirable to introduce an additive into the starting material in step 640. The additive can be used to modify the property imposed by the crystallization nucleation site, or to impart new properties to the crystalline structure. For example, the additive can be one or more of ions, dopants, proteins, polymers, fluorescent molecules, or drugs, as discussed above in the context of FIGS. 1-5.

As also illustrated in FIG. 6, the method can include a step 650 of contacting the crystallization starting material with a second surface of a second substrate. The second surface maintains the crystallization starting material in an amorphous state or crystalline state that is different than the desired crystalline structure. The second surface can comprise a second self-assembling monolayer such as discussed in the context of FIGS. 1-5.

In step 660, crystal growth is stopped. Crystallization may, e.g., stop when all of the starting material has been converted into the crystalline structure. When there is a plurality of physically separated crystallization nucleation sites, crystallite growth can be stopped prior to the growing crystallites fusing together by physically separating the crystallization nucleation sites far enough from each other and not allowing the crystallization to proceed too long. Alternatively, predefined amounts of starting material can be contacted to each crystallization nucleation site to provide a crystalline structure of a given size.

In still other cases, at the desired time period, additives that interact with crystals and passivate crystal surfaces can be introduced to inhibit crystal growth, thus limiting the crystal size and morphology. In still other instances, of course, crystallite growth can be allowed to continue so as to form an interconnected network of crystalline structures. For example, crystallite growth initiated from a plurality of locations can be allowed to continue until the crystallites intergrow or fuse with each other to form the interconnected network of crystallites. In some cases, the method can be used to form both physically separated and interconnected networks of the crystallization nucleation sites on different regions of the substrate surface.

By choosing the location and time to grow the crystalline structures, various components can be produced by the method. For instance, the method 600 can comprise a step 670 of producing a tissue replacement material comprising the crystalline structure. Alternatively, the method 600 can comprise a step 680 of producing an optical or electrical circuit on. the substrate such that the crystalline structure is a component of the circuit. For instance, the crystalline structure can form active channels or dielectric layers of field-effect transistors in the circuit, such as illustrated in FIG. 4. Alternatively, the crystalline structure can form a birefringent material or other optical components of the circuit, such as illustrated in FIG. 5.

Although the present invention has been described in detail, those of ordinary skill in the art should understand that they could make various changes, substitutions and alterations herein without departing from the scope of the invention.

What is claimed is:

1. An apparatus, comprising:
a substrate having a surface with at least one crystallization nucleation site located thereon; and
a second substrate having a second surface, wherein the second surface is configured to maintain a crystallization starting material in an amorphous state or an initial crystalline state, and
wherein the crystallization nucleation site is configured to impose a property on the crystallization starting material.

2. The apparatus of claim 1, wherein the crystallization starting material comprises an amorphous material.

3. The apparatus of claim 1, wherein the crystallization nucleation site comprises a self-assembling monolayer.

4. The apparatus of claim 1, wherein the imposed property is displayed by a crystalline structure formed from the crystallization starting material.

5. The apparatus of claim 1, wherein the imposed property is a predefined crystalline morphology, polymorph, orientation, location of the surface, or pattern on the surface.

6. The apparatus of claim 1, wherein the crystallization starting material comprises a tissue replacement material.

7. The apparatus of claim 1, further comprising an electrical or optical circuit on the surface.

8. The apparatus of claim 7, wherein the circuit includes field-effect transistors having active channels comprising crystallites made of the crystallization starting material.

9. The apparatus of claim 7, wherein the circuit includes an optical beam splitter, wherein the crystallization starting material comprises a birefringent material of the optical beam splitter.

10. A method, comprising:
providing a substrate with a surface, a crystallization nucleation site located on the surface;
contacting the crystallization starting material with a second surface of a second substrate, wherein the second surface maintains a crystallization starting material in an amorphous state or an initial crystalline state until the crystallization starting material contacts the crystallization nucleation site; and
growing a crystalline structure from the crystallization starting material on the crystallization nucleation site by changing a property of the crystallization starting material imposed by the crystallization starting material.

11. The method of claim 10, wherein the second surface maintains the crystallization starting material in the amorphous state until the crystallization starting material contacts the crystallization nucleation site.

12. The method of claim 10, wherein the crystallization starting material comprises an additive configured to affect the property of the crystalline structure.

13. The method of claim 10, wherein the crystallization nucleation site comprises a self-assembling monolayer.

14. The method of claim 10, the crystallization starting material comprises organic semiconducting molecules.

15. The method of claim 10, where the surface comprises one or both of physically separated crystallization nucleation sites or an interconnected network of crystallization nucleation sites.

16. The method of claim 15, further comprising stopping the growth prior to the crystalline structures fusing together.

17. The method of claim 10, wherein changing the property comprises changing the starting material from an amorphous state to the crystalline structure.

18. The method of claim 10, further comprising producing a tissue replacement material comprising the crystalline structure.

19. The method of claim 10, further comprising producing an optical or electrical circuit on the substrate such that the crystalline structure is a component of the circuit.

20. The method of claim 10, wherein the crystalline structure form active channels of field-effect transistors.
